(19) United States
(12) Patent Application Publication
(10) Pub. No.: US 2005/0233263 A1
(43) Pub. Date: Oct. 20, 2005

(54) Growth of carbon nanotubes at low temperature

(75) Inventors: Beom Soo Park, San Jose, CA (US); Soo Young Choi, Fremont, CA (US); John M. White, Hayward, CA (US)

Correspondence Address: MOSER, PATTERSON & SHERIDAN, LLP;APPLIED MATERIALS, INC., 3040 POST OAK BOULEVARD, SUITE 1500, HOUSTON, TX, 77056, US

(73) Assignee: APPLIED MATERIALS, INC.

(21) Appl. No.: 10/827,915

(22) Filed: Apr. 20, 2004

(51) Int. Cl. G03F 7/00

(52) U.S. Cl. 430/324; 430/322

(57) ABSTRACT

A method for depositing carbon nanotubes on a large substrate is provided. The carbon nanotubes are deposited on a plasma treated transition metal layer on a substrate. In one aspect, the transition metal layer is treated with a plasma of argon or a mixture of nitrogen and hydrogen. The carbon nanotubes are deposited by thermal chemical vapor deposition at a substrate temperature of between about 400° C. and about 450° C.

### BACKGROUND OF THE INVENTION

1. Field of the Invention

Embodiments of the present invention generally relate to the deposition of carbon nanotubes. More particularly, embodiments of the invention relate to the deposition of carbon nanotubes on flat panel substrates, such as substrates having an area of at least about 370 mm×470 mm, at low temperatures.

2. Description of the Related Art

Field emission devices or displays (FEDs) are currently being developed for use in a variety of electronic equipment. In particular, FEDs are being developed for use in flat panel displays. In contrast to cathode ray tubes (CRTs) which use an electron gun such as a single tungsten filament as an electron source to produce images on a screen, FEDs use multiple electron sources in the form of emitter tips.

An example of a FED 100 is shown in FIG. 1 (Prior Art). FED 100 includes a substrate 101, which is typically a glass substrate. A conductive layer 102 serves as a cathode. A dielectric layer 104 is formed on the conductive layer 102, and a metal gate layer 106 is formed on the dielectric layer 104. Regions of emitter tips 108 are formed on the conductive layer 102 between the regions of the dielectric layer 104 on the conductive layer 102. Phosphors 110 are formed on a conductive layer 112 that serves as an anode. The conductive layer 112 is formed on an upper substrate 114, which is typically a glass substrate. Phosphors 110 are aligned with the emitter tips 108 such that electrons emitted from the emitter tips in one region of the conductive layer 102 when a voltage is applied between the cathode and anode travel to the corresponding aligned phosphor 110.

Typically, conductive emitter tips, such as molybdenum emitter tips, or semiconductive emitter tips, such as silicon emitter tips, have been used in FEDs. Recently, carbon nanotube (CNT) emitter tips have been developed. Electrons can be released from CNTs at low voltages, and thus, CNTs are becoming a preferred emitter tip material.

While much research has been done on the formation of CNTs for various technologies, the formation of uniform CNTs across large substrates has remained a challenge. Variations in temperature and processing conditions across large substrates can result in the formation of CNTs having differing properties, such as a variety of widths and lengths and emitter tip shapes, which can result in image non-uniformity across a large flat panel display.

Thus, there remains a need for a method of depositing CNTs across large substrates.

### SUMMARY OF THE INVENTION

Embodiments of the invention generally provide a method of processing a substrate that includes plasma treating a patterned transition metal layer on a substrate and depositing carbon nanotubes on the plasma treated transition metal layer at a substrate temperature of between about 400° C. and about 450° C. The carbon nanotubes are deposited by a thermal chemical vapor deposition process in the absence of a plasma or RF power.

In one embodiment, a transition metal layer is deposited on a substrate, patterned, and plasma treated. Carbon nanotubes are deposited on the plasma treated transition metal layer at a substrate temperature of between about 400° C. and about 450° C.

In a further embodiment, a transition metal layer is deposited on a substrate, patterned, and plasma treated at an RF power of between about 1 kilowatt and about 2 kilowatts. Carbon nanotubes are deposited on the plasma treated transition metal layer at a substrate temperature of between about 400° C. and about 450° C.

In another embodiment, a transition metal layer is deposited on a substrate and plasma treated with a plasma comprising argon or a mixture of nitrogen and hydrogen. Carbon nanotubes are deposited on the plasma treated transition metal layer at a substrate temperature of between about 400° C. and about 450° C.

Another embodiment of the invention provides a process chamber comprising a chamber body, a substrate support, an RF power source adapted to provide RF power to plasma treat a substrate on the substrate support, and a gas inlet manifold configured to introduce a mixture comprising a hydrocarbon into the chamber body, wherein the substrate support is adapted to heat the substrate thereon to a temperature of between about 400° C. and about 450° C. during deposition of carbon nanotubes on a patterned transition metal layer on the substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a schematic, cross-sectional view of a prior art FED.

FIG. 2 illustrates a process sequence according to an embodiment of the invention.

FIG. 3 depicts a schematic, cross-sectional view of a structure processed according to embodiments described herein.

FIG. 4 depicts a schematic, cross-sectional view of a process chamber that may be used to practice embodiments described herein.

### DETAILED DESCRIPTION OF THE PREFERRED EMBODIMENT

Embodiments of the invention include a method of depositing carbon nanotubes on a substrate. The carbon nanotubes are deposited on a substrate by a thermal, non-plasma enhanced, chemical vapor deposition (CVD) process, wherein the substrate is maintained at a temperature between about 400° C. and about 450° C.

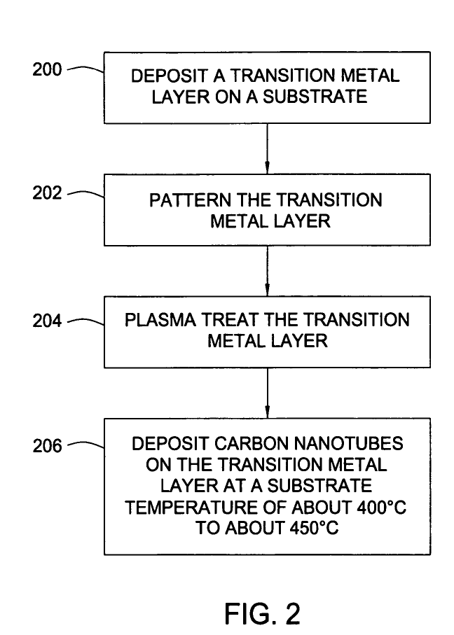

An example of a process sequence that may be used to deposit the carbon nanotubes is summarized in FIG. 2 and will be described in further detail below. A transition metal layer is deposited on a substrate, as shown in step 200. The transition metal layer is patterned, as shown in step 202. The transition metal layer is plasma treated in step 204. Carbon nanotubes are deposited on the plasma treated transition metal layer at a substrate temperature of between about 400° C. and about 450° C., as shown in step 206.

The substrate on which the carbon nanotubes are subsequently deposited is typically a glass substrate. The substrate may have an area of at least about 173,900 mm² (e.g., a 370 mm×470 mm substrate), or even greater than about 671,600 mm² (e.g., a 730 mm×920 mm substrate). In one aspect, the substrate has an area between about 173,900 mm² and about 671,600 mm². The transition metal layer comprises a transition metal, such as nickel (Ni), chromium (Cr), iron (Fe), cobalt (Co), or combinations thereof. The transition metal layer may be deposited by any of a number of processes, including chemical vapor deposition (CVD), physical vapor deposition (PVD), an electrochemical process, or combinations thereof. Preferably, the transition metal layer is deposited by a sputtering process such as PVD. For example, a transition metal such as Co, Ni, or Fe may be sputtered with argon at a temperature of less than about 200° C. and a pressure of about 1×10⁻⁵ Torr to about 1×10⁻⁶ Torr to deposit the transition metal layer. The transition metal layer serves as a catalytic seed layer for the formation of carbon nanotubes thereon. The transition metal layer may be about 10 Å to about 200 Å thick. Carbon nanotubes having smaller radii can be formed if a thinner transition metal layer is deposited.

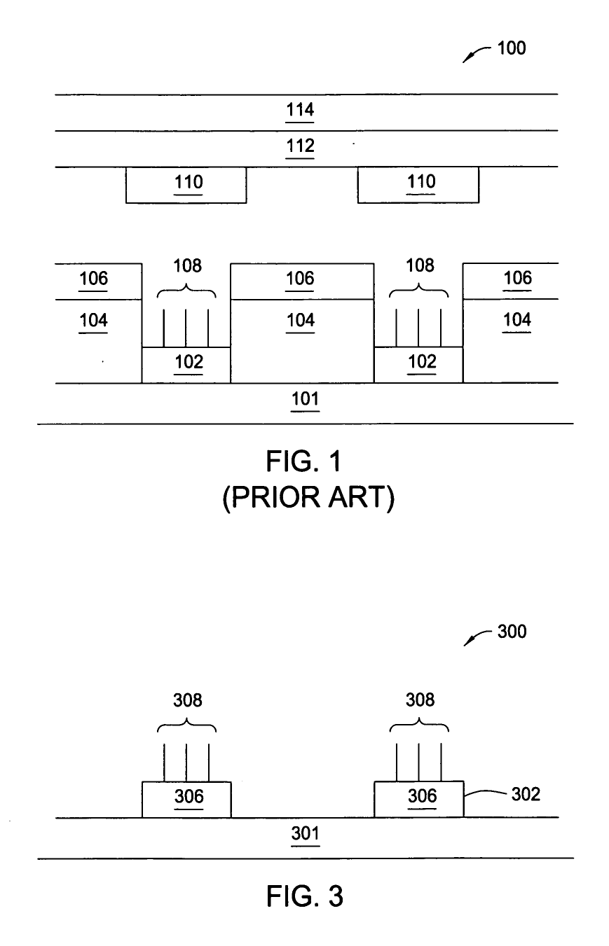

In one embodiment, the transition metal layer is patterned before the transition metal layer is plasma treated. The patterning of the transition metal layer may be performed with conventional photolithography processes. An example of a structure 300 including a patterned transition metal layer is shown in FIG. 3. Structure 300 includes a substrate 301 and a transition metal layer 302 thereon. The transition metal layer is patterned to form isolated regions 306 of the transition metal layer 302 on the substrate 301. The isolated regions 306 of the transition metal layer 302 serve as nucleation sites for carbon nanotubes 308. By forming isolated regions of the transition metal layer 302, isolated regions of carbon nanotubes that function as emitter tips can be formed on the transition metal layer 302. Phosphors on an upper substrate can be aligned with the isolated regions of the carbon nanotubes to form a FED as shown in FIG. 1. The isolated regions may serve as pixels or sub-pixels in a display.

Preferably, the substrate is heated before the substrate is plasma treated. For example, the substrate may be heated to a temperature of between about 400° C. and about 450° C. for about 1 to about 5 minutes. The substrate is then plasma treated. The substrate may be plasma treated in the same chamber or in a different chamber. The plasma may include argon (Ar) or a mixture of nitrogen (N₂) and hydrogen (H₂). It is believed that the argon plasma and nitrogen/hydrogen plasma treat the substrate by physical bombardment. Preferably, the plasma includes or is an argon plasma, as smaller diameter carbon nanotubes can be formed when an argon plasma treatment is used with suitable plasma treatment conditions, such as 1.5-2 kilowatts RF power for 10 minutes for a 370 mm×470 mm substrate. An argon flow of between about 500 sccm and about 2000 sccm may be used for a chamber for a 400 mm×500 mm substrate. The gas flow rate may be adjusted for other chamber sizes. The plasma treatment may be performed with between about 1 and about 2 kilowatts RF power at a spacing of between about 500 and about 100 mils for about 2 to about 10 minutes at a substrate temperature of between about 400° C. and about 450° C. in a chamber such as the AKT 1600 PECVD chamber, available from Applied Materials, Inc., Santa Clara, Calif.

The plasma treatment generates nucleation sites or seeds in the transition metal layer for the deposition of the carbon nanotubes at low temperatures. The radii of the nucleation sites, and thus, the radii of the carbon nanotubes, can be adjusted by adjusting the processing conditions of the plasma treatment. For example, increasing the power density during the plasma treatment and/or increasing the length of the plasma treatment can reduce the radius of the carbon nanotubes.

After the transition metal layer is plasma treated, carbon nanotubes are deposited, i.e., formed, on the transition metal layer. The carbon nanotubes are deposited by a thermal, non-plasma enhanced CVD process at a substrate temperature of between about 400° C. and about 450° C., preferably between about 400° C. and about 430° C. The carbon nanotubes are deposited in the absence of RF power. The carbon nanotubes may be deposited at a pressure of between about 4 Torr and about 8 Torr. The nanotubes are deposited from a mixture comprising a hydrocarbon. For example, acetylene (C₂H₂), methane (CH₄), ethylene (C₂H₄), or combinations thereof may be used as the hydrocarbon. The mixture may also include a nitrogen source, such as ammonia (NH₃), nitrogen (N₂), or a combination thereof, and a carrier gas, such as hydrogen (H₂), argon (Ar), or helium (He). Preferably, the ratio of the hydrocarbon to carrier gas to nitrogen source is about 1:0.5-1:1-3.

In a preferred embodiment, a gas mixture of C₂H₂, H₂, and NH₃ is used to deposit the carbon nanotubes. For a chamber for a 370 mm×470 mm glass substrate, a C₂H₂ flow rate of about 100 sccm to about 300 sccm, a H₂ flow rate of about 50 sccm to about 300 sccm, and a NH₃ flow rate of about 100 sccm to about 900 sccm may be used. Flow rates may be adjusted according to the chamber size used.

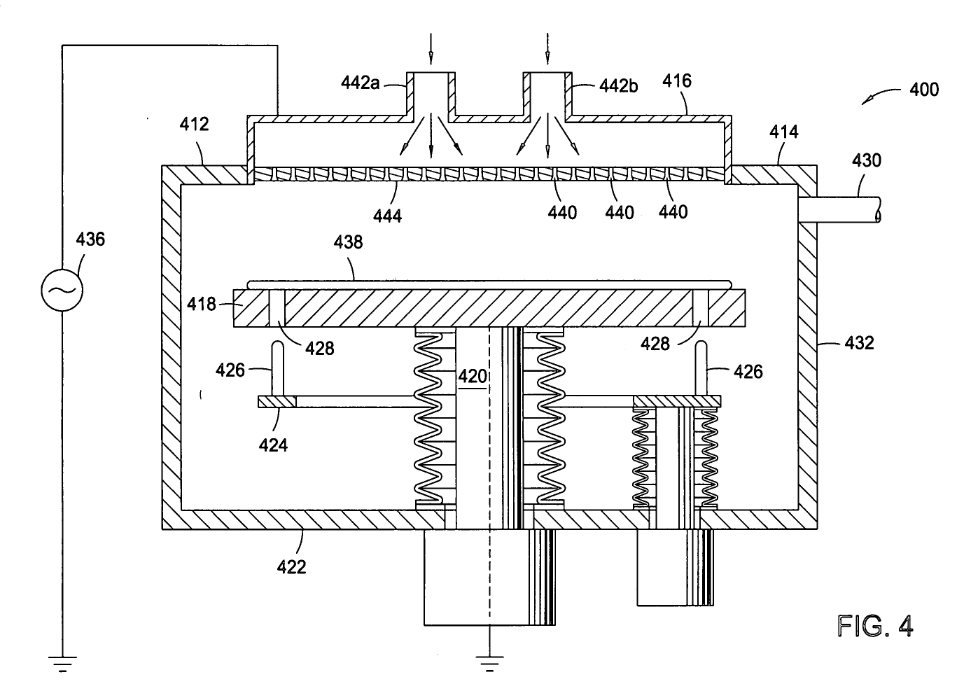

An example of a chamber apparatus that may be used to plasma treat the transition metal layer and deposit carbon nanotubes thereon is shown in FIG. 4. Apparatus 400 comprises a chamber body 412 that has a top wall 414 with an opening therethrough and a first electrode 416 that can act as a gas inlet manifold within the opening. Alternatively, the top wall 414 can be solid with the electrode 416 being adjacent to the inner surface of top wall 414. Within chamber body 412 is a susceptor 418 in the form of a substrate support plate that extends parallel to the first electrode 416. The susceptor 418 may be made of aluminum and coated with a layer of aluminum oxide. The susceptor 418 is connected to ground so that it serves as a second electrode. The susceptor 418 also includes a heating element (not shown) that may be used to heat a substrate without applying RF power to the electrodes. The susceptor 418 is mounted on the end of a shaft 420 that extends vertically through a bottom wall 422 of the deposition chamber body 412. The shaft 420 is movable vertically so as to permit movement of the susceptor 418 vertically toward and away from the first electrode 416. A lift-off plate 424 extends horizontally between the susceptor 418 and the bottom wall 422 of the deposition chamber body 412 substantially parallel to the susceptor 418. Lift-off pins 426 project vertically upwardly from the lift-off plate 424. The lift-off pins 426 are positioned to be able to extend through holes 428 in the susceptor 418, and are of a length slightly longer than the thickness of the susceptor 418. While there are only two lift-off pins 426 shown in the figure, there may be more lift-off pins 426 spaced around the lift-off plate 424.

A gas outlet 430 extends through a side wall 432 of the deposition chamber body 412 and is connected to means (not shown) for evacuating the deposition chamber body 412. One or more gas inlet pipes 442a, 442b extend through the first electrode 416 of the deposition chamber body 412, and are connected through a gas switching network (not shown) to sources (not shown) of various gases. Gases introduced into the chamber through the one or more gas inlet pipes 442a, 442b pass through holes 440 in a diffuser or showerhead 444 in the upper portion of the deposition chamber body 412. The first electrode 416 is connected to an RF power source 436. A transfer plate (not shown) is typically provided to carry substrates through a load-lock door (not shown) into the deposition chamber body 412 and onto the susceptor 418, and also to remove the coated substrate from the deposition chamber body 412.

In the operation of the process chamber 400, a substrate 438 is first loaded into the deposition chamber body 412 and is placed on the susceptor 418 by the transfer plate (not shown). The substrate 438 is of a size to extend over the holes 428 in the susceptor 418. The susceptor 418 lifts the substrate 438 off the lift-off pins 426 by moving shaft 420 upwards such that the lift-off pins 426 do not extend through the holes 428, and the susceptor 418 and substrate 438 are relatively close to the first electrode 416. The electrode spacing or the distance between the substrate surface and the discharge surface of the first electrode 416 may be optimized depending on the kind of precursor and process gas used, as well as on the desired properties of the resulting film.

An example of a chamber similar to the chamber shown and described with respect to FIG. 4 is an AKT 1600 PECVD chamber, available from Applied Materials Inc., Santa Clara, Calif. The AKT 1600 PECVD chamber has a volume of about 48 liters and may be used to process a 370 mm by 470 mm substrate.

While a CVD chamber capable of plasma enhanced CVD is provided above for the deposition of the carbon nanotubes, a conventional CVD chamber without plasma capability may be used for the deposition of the carbon nanotubes, as the carbon nanotubes are deposited by a thermal, non-plasma enhanced process.

Embodiments of the invention are further illustrated by the following example which is not intended to limit the scope of the invention.

### EXAMPLE

A 100 Å nickel layer was deposited on a 370 mm×470 mm glass substrate and patterned using photolithography. The substrate was then placed in an AKT 1600 PECVD chamber and heated to a temperature of 420° C. for 5 minutes. RF power in the chamber was then turned on, and the substrate was treated with an argon plasma for 5 minutes at an argon flow rate of 700 sccm, a RF power of 2 kW at 13.56 MHz, and a spacing of 1000 mils. The RF power was then turned off. Acetylene (C₂H₂) was introduced into the chamber at about 200 sccm, hydrogen (H₂) was introduced into the chamber at about 150 sccm, and ammonia (NH₃) was introduced into the chamber at about 100 sccm. Carbon nanotubes were deposited on the transition metal layer at a substrate temperature of 420° C. and a chamber pressure of 4 Torr. The carbon nanotubes were deposited for a period of 10 minutes. About 2 μm of carbon nanotubes having a diameter of approximately 10 nm were deposited.

TEMs of carbon nanotubes deposited according to embodiments described herein show that the carbon nanotubes are deposited in an ordered, directional alignment that is desirable for use in FEDs. It is believed that the plasma treatment of the transition metal layer provided herein creates nucleation sites in the transition metal layer that are conducive to the formation of directional carbon nanotubes.

A low substrate temperature of between about 400° C. and about 450° C. during the deposition of the carbon nanotubes is another advantage provided according to embodiments herein. It is believed that a substrate temperature of at least 400° C. promotes the formation of carbon nanotubes with structural characteristics sufficient for use in FEDs. It is believed that a substrate temperature of 450° C. or less minimizes damage to the substrate. Many prior methods of carbon nanotube deposition use a substrate temperature of up to 950° C. or the presence of a plasma during deposition. Uniformly heating a large glass substrate to high temperatures can be quite difficult. High temperatures can also damage the substrate or layers deposited on the substrate. Creating uniform plasma conditions across a large substrate can also be difficult.

Thus, embodiments of the invention provide an improved method for the deposition of carbon nanotubes on a substrate.

While the foregoing is directed to embodiments of the present invention, other and further embodiments of the invention may be devised without departing from the basic scope thereof, and the scope thereof is determined by the claims that follow.

1. A method of processing a substrate having a patterned transition metal layer comprising:
plasma treating the patterned transition metal layer; and then
depositing carbon nanotubes on the patterned transition metal layer at a substrate temperature of between about 400° C. and about 450° C.

2. The method of claim 1, wherein the substrate having a patterned transition metal layer is produced by:
depositing a transition metal layer on the substrate; and
patterning the transition metal layer.

3. The method of claim 2, wherein the carbon nanotubes are deposited in the absence of RF power.

4. The method of claim 2, wherein the plasma treating generates nucleation sites in the patterned transition metal layer for the carbon nanotubes.

5. The method of claim 2, wherein the patterning the transition metal layer comprises a photolithography process.

6. The method of claim 2, further comprising heating the substrate before the plasma treating.

7. The method of claim 2, wherein the substrate is a glass substrate having an area of at least about 173,900 mm².

8. The method of claim 2, wherein the substrate temperature is between about 400° C. and about 430° C.

9. The method of claim 2, wherein the transition metal layer comprises a material selected from the group consisting of nickel, chromium, iron, cobalt, and combinations thereof.

10. The method of claim 2, wherein the carbon nanotubes are deposited from a mixture comprising C₂H₂, H₂, and NH₃.

11. A method of processing a substrate, comprising:
depositing a transition metal layer on the substrate;
plasma treating the transition metal layer with a plasma comprising argon or a mixture of nitrogen (N₂) and hydrogen (H₂); and
depositing carbon nanotubes on the plasma treated transition metal layer at a substrate temperature of between about 400° C. and about 450° C.

12. The method of claim 11, wherein the carbon nanotubes are deposited in the absence of RF power.

13. The method of claim 11, wherein the plasma comprises argon.

14. The method of claim 11, further comprising patterning the transition metal layer with a photolithography process.

15. The method of claim 11, further comprising heating the substrate before the plasma treating.

16. The method of claim 11, wherein the substrate is a glass substrate having an area of at least about 173,900 mm².

17. A method of processing a substrate, comprising:
depositing a transition metal layer on the substrate;
patterning the transition metal layer;
treating the transition metal layer with a plasma at an RF power of between about 1 kilowatt and about 2 kilowatt; and
depositing carbon nanotubes on the plasma treated transition metal layer at a substrate temperature of between about 400° C. and about 450° C.

18. The method of claim 17, wherein the carbon nanotubes are deposited in the absence of RF power.

19. The method of claim 17, wherein the plasma comprises argon or a mixture of nitrogen (N₂) and hydrogen (H₂).

20. The method of claim 17, wherein the plasma comprises argon.

21. A process chamber comprising:
a chamber body;
a substrate support;
an RF power source adapted to provide RF power to plasma treat a substrate on the substrate support; and
a gas inlet manifold configured to introduce a mixture comprising a hydrocarbon into the chamber body, wherein the substrate support is adapted to heat the substrate thereon to a temperature of between about 400° C. and about 450° C. during deposition of carbon nanotubes on a patterned transition metal layer on the substrate.
